(19) United States
(12) Patent Application Publication
(10) Pub. No.: US 2009/0206923 A1
(43) Pub. Date: Aug. 20, 2009

(54) FILTER SWITCHING DEVICE AND FILTER SWITCHING METHOD

(75) Inventor: Syunsuke Shiobara, Tokyo (JP)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 12/057,770

(22) Filed: Mar. 28, 2008

Related U.S. Application Data
(60) Provisional application No. 61/065,965, filed on Feb. 14, 2008.

(51) Int. Cl. H03H 11/04

(52) U.S. Cl. 327/553

(57) ABSTRACT

A filter switching device includes a first buffer amplifier, a first characteristic resistor with one terminal connected to the output of the first buffer amplifier, first and second filter circuits connected in parallel to the other terminal, the first filter circuit including a first relay and a first low-pass filter, the second filter circuit including a second relay and a second low-pass filter, a third filter circuit connected to the output of the first buffer amplifier, having a second buffer amplifier and a second characteristic resistor connected between the output of the second buffer amplifier and a third low-pass filter, and a multiplexer connected between the first, second, and third filter circuits and a third characteristic resistor selectively connecting the first, second, or third filter circuit to the third characteristic resistor.

The disclosed embodiments relate to a signal generator and in further detail, to technology for a filter switching device connected to the output step (output stage) of a signal generator.

### BACKGROUND

In the past, signal generators such as the Agilent Technologies, Inc. Pulse Pattern Generator 81110A have been capable of outputting as the output signals not only the alternating-current component, that is, the AC component, but of outputting signals together with a predetermined direct-current component, that is, the DC component (DC offset).

Moreover, multiple filters, such as a plurality of low-pass filters, are disposed at the output stage of the signal generator, filters optimal for the frequency of the signals that will be output are connected, and unnecessary frequency components have been eliminated as necessary. For example, FIG. 1 of JP (Kokai) Unexamined Patent Publication 7-20211 discloses a signal generator having multiple filters 55 and 56 with which the high-frequency component is eliminated. In addition, paragraphs [0016] and [0017] of this reference cite that once filter 55 or 56 has been connected by switches SW1 through SW4, signals are output.

In order to facilitate an understanding of the above-mentioned technology, FIG. 3 of the present specification is taken from FIG. 1 of the above-mentioned reference. Here, 1 is a DUT, 2 is a controller, 3 is a timing generation part, 4 is a digital signal generation part for digital signal output, 5 is an analog waveform generation part, 51 is a digital signal generation part for analog waveform output, 52 is a FIFO, 53 is a register, 54 is a D/A conversion part (digital to analog conversion part), 55 and 56 are filters for eliminating different frequency components, 57a, 57b, and 57c are programmable delay lines, 58 is a delay amount memory, a, b, c, and d are clocks, e is a digital signal, f, g, and h are digital values, and i is the analog waveform.

Moreover, FIG. 3 of JP (Kokai) Unexamined Patent Publication 1-218201 shows an example of a signal structure having an AWG (arbitrary waveform generator) structure wherein the operator-preferred waveform data is stored in a large-capacity waveform memory.

However, as a result of the progress in electronic devices in recent years, there has been an increase in the necessity for complex signals in electronic device testing. One such example is the case wherein the frequency of AC signals (that is, the AC component) is switched while applying DC bias (that is, DC offset) in order to test changes in device properties. Nevertheless, conventional signal generators and filter switching circuits have not taken into consideration the switching of the AC component frequency of output signals while the output of the DC component continues intact. In such a case, once signal output has stopped, the AC component frequency setting is changed and the filter to be used is newly connected, then signal output is restarted.

Consequently, a filter switching circuit, that is, a filter switching device, for switching filters matching signals from a signal generator that is connected to the signal generator requires a filter switching device and a switching method with which the output signals are not affected by being interrupted or discontinued as a result of this switching.

### SUMMARY

The disclosed embodiments provide a filter switching device and a method for a filter switching device connected to a signal generator that outputs the AC component and the DC component over one another with which, when the AC signal output of a first frequency is stopped but the DC component output continues intact and the output of an AC signal of a second frequency is started, it is possible to switch to the desired filter without stopping or discontinuously changing of the output of signals having a DC component alone.

The filter switching device of the disclosed embodiments includes:
first and second low-pass filters;
a third low-pass filter having the lowest cutoff frequency;
a first buffer amplifier for buffering and amplification of input signals;
a first characteristic resistor wherein one terminal is connected to the output of the first buffer amplifier;
first and second filter circuits connected in parallel to the other terminal of the first characteristic resistor, wherein, of the first and second filter circuits, the first filter circuit comprises a first relay and the first low-pass filter, the second filter circuit comprises a second relay and the second low-pass filter, and the first and second relays selectively turn on and off the signals to be transmitted to the first and second filters, respectively;
a third filter circuit connected to the output of the first buffer amplifier, wherein the third filter circuit comprises a second buffer amplifier for buffering and amplification of signals that have been transmitted to the third filter circuit, a second characteristic resistor connected to the output of the second buffer amplifier, and the third low-pass filter, and the output signals of the first buffer amplifier can always be transmitted to the third low-pass filter by the second buffer amplifier; and
a multiplexer for outputting signals that is connected to the first, second, and third filter circuits and a third characteristic resistor and selectively connects the first, second, or third filter circuit to the third characteristic resistor.

The above-mentioned embodiment also includes embodiments wherein, when the filter circuit matching the input signals is switched from the first filter circuit to the second filter circuit in accordance with the input signals, the multiplexer switches in such a way that the third filter circuit is selected in place of the first filter circuit, then the first relay is opened and the second relay is closed, and then the multiplexer switches in such a way that the second filter circuit is selected in place of the third filter circuit.

Moreover, the filter switching method disclosed herein is a filter switching method for a filter switching device comprising
a first buffer amplifier for buffering and amplification of input signals and
an output switching circuit wherein the buffered and amplified input signals are sent to first and second filter circuits; the first and second filter circuits comprise respective first and second relays that selectively turn on and off the first and second low-pass filters, and buffer and amplify the input signals using a second buffer amplifier and send these signals to a third filter circuit; and the third filter circuit comprises a third low-pass filter having the lowest cutoff frequency and selectively outputs the signals of the first, second, and third filter circuits,
said method primarily characterized in that when the filter circuit matching the input signals is switched from the first filter circuit to the second filter circuit in accordance with the input signals,
the output switching circuit is switched in such a way that the third filter is selected in place of the first filter circuit,
then the first relay is opened and the second relay is closed, and
then the output switching circuit is switched in such a way that the second filter circuit is selected in place of the third filter circuit.

Furthermore, the above-mentioned method also includes embodiments wherein the output switching circuit is a multiplexer and wherein the input signals input to the second buffer amplifier are input signals that have been buffered and amplified by the first buffer amplifier.

### BRIEF DESCRIPTION OF THE DRAWINGS

FIG. 1 is a circuit diagram of a filter switching device according to the disclosed embodiments;

FIG. 2 is a circuit diagram of another filter switching device in accordance with the disclosed embodiments;

FIG. 3 is a block diagram of a signal generator comprising a filter switching circuit of the prior art; and

FIG. 4 is the circuit diagram of the filter switching device of the prior art in FIG. 3.

### DETAILED DESCRIPTION

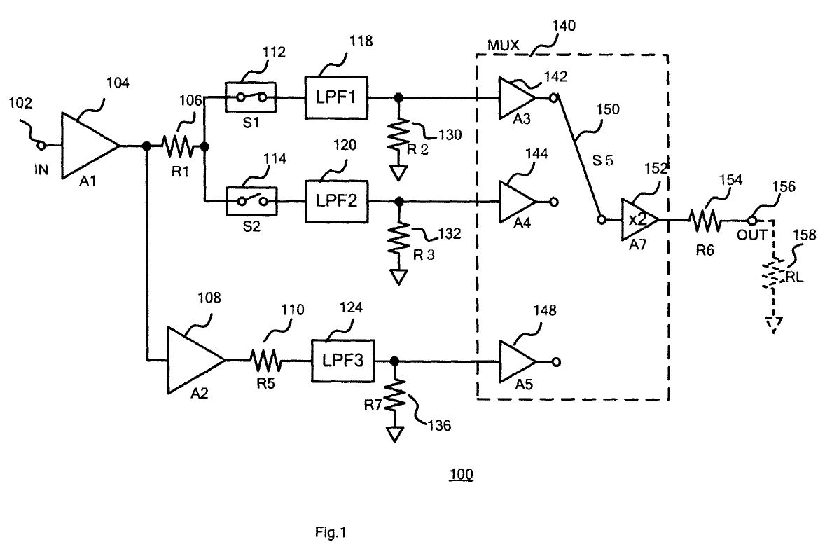

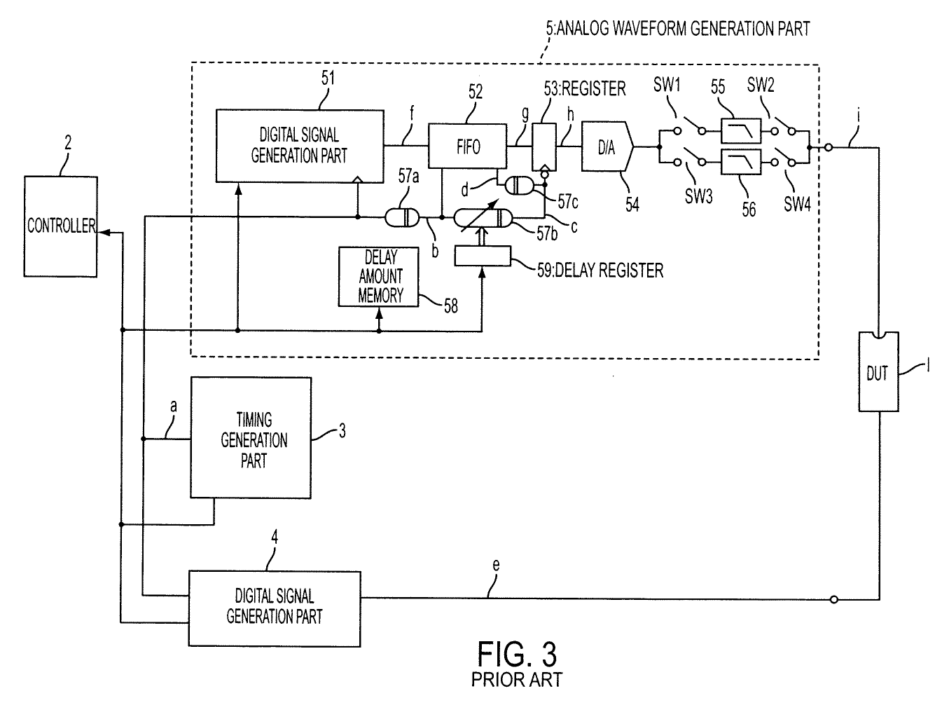

First, the problems when attempting to use the device of the prior art of FIG. 3 according to the disclosed embodiments will be described and then the disclosed embodiments will be described using FIG. 1.

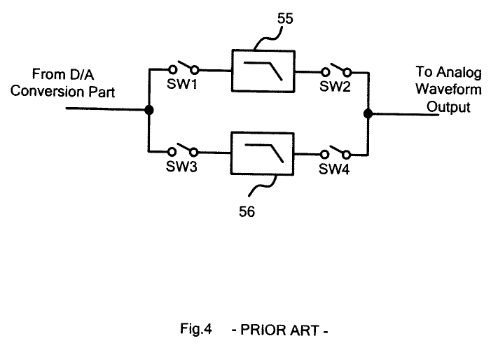

The filter switching circuit of the output stage of the circuit in FIG. 3 is shown in FIG. 4 as a filter switching circuit 500. There are two general methods by which this conventional switching circuit 500 can be used according to the disclosed embodiments, A) switching by break-before-make control and B) make-before-break control.

First, switching from filter 55 to filter 56 using A) break-before-make will be discussed. By means of this method, control is accomplished by the following steps:
A1) SW1 and SW2 are closed and SW3 and SW4 are opened. Signals are output from the D/A conversion part and signals obtained by overlapping the DC component and the AC component are transmitted. The signals obtained by overlapping the DC component and the AC component are output to the analog waveform output terminal after filter 55 has removed the high-frequency component.
A2) Next, the output of the AC component is stopped by the D/A conversion part. However, the output of the DC component continues.
A3) SW1 and SW2 are opened and then SW3 and SW4 are closed. As a result, the selected filter is switched from filter 55 to filter 56.
A4) The output of the AC component of a frequency different from the above-mentioned from the D/A conversion part is overlapped with the DC component and started.

By means of the above-mentioned procedure, signals from the D/A conversion part are first applied to filter 56 by closing SW3 and SW4 at step A3. Nevertheless, filters generally comprise capacitors and therefore, the discontinuous and unstable signal output of the DC component is monitored at the analog waveform output terminal until charging of the capacitor inside filter 56 is completed. Consequently, the disclosed embodiments cannot be realized, even if the break-before-make control method is used in circuit 500.

Switching from filter 55 to 56 using B) make-before-break control will now be discussed. By means of this method, control is accomplished by the following steps.
B1) SW1 and SW2 are closed and SW3 and SW4 are opened. Signals are output from the D/A conversion part and signals obtained by overlapping the DC component and AC component are transmitted. Signals obtained by overlapping the DC component and AC component are output to the analog waveform output terminal once the high-frequency component has been cut off, that is, eliminated, by filter 55.
B2) Next, the output of the AC component is stopped by the D/A conversion part. However, the output of the DC component continues.
B3) SW3 and SW4 are closed and SW1 and SW2 are opened.
B4) The output of the AC component of a frequency different from the above-mentioned from the D/A conversion part is overlapped with the DC component and started.

By means of the above-mentioned procedure, signals from the D/A conversion part are first applied to filter 56 by closing SW3 and SW4 at step B3, but the output voltage to the analog waveform output changes due to the effect of the charging current flowing to the capacitor inside filter 56.

It should be noted that there is another method whereby, in step B3, first SW3 is closed, then SW4 is closed and SW2 is opened, and then SW1 is opened. Nevertheless, when SW3 is closed, charging current flows into the capacitor of filter 56; therefore, the inconvenience of monitoring this effect as changes in the output voltage of the filter circuit is not eliminated.

The disclosed embodiments cannot be accomplished by using the method of the prior art in FIG. 4 for the filter switching device.

FIG. 1 shows a filter switching device 100 in accordance with the embodiments disclosed herein.

In filter switching device 100, IN (102) is an input terminal, A1 (104) and A2 (108) are buffer amplifiers, and OUT (156) is an output terminal. Resistors R1 (106), R5 (110), and R6 (154) are characteristic resistors for giving the characteristic impedance necessary for adjusting the impedance of device 100, and resistors R2 (130), R3 (132), and R7 (136) are terminal resistors. For easy understanding, load resistor RL (158) is shown at output terminal OUT (156), but this is not a structural element of device 100.

It should be noted that the value of characteristic resistors R1, R5, and R6 and of terminal resistors R2, R3, R7, and RL is preferably 50Ω, but these resistors are not limited to this value and can be another value, such as 75Ω or 100Ω.

S1 (112) and S2 (114) are relays. Relays 112 and 114 preferably are photo MOS semiconductor relays (Photo MOS relays) that operate at high speed and have high insulation performance, but other types of relays may also be used.

LPF1 (118), LPF2 (120), and LPF3 (124) are low-pass filters that eliminate or attenuate the high-frequency component. Of these, LPF3 (124) is the low-pass filter having the lowest cutoff frequency among the three low-pass filters, that is, the filter for eliminating the high-frequency component from the lowest frequency among the three low-pass filters.

LPF3 (124) is the low-pass filter having the lowest cutoff frequency; therefore, buffer amplifier A2 (108) is not necessarily as high speed as buffer amplifier A1 (104). Consequently, it should be noted that this has the effect of keeping the cost of the device low.

Multiplexer MUX (140) acts as an output switching circuit that is connected to resistor R6 (154) and that selects among the low-pass filters, and in the present embodiment a 3 inputs/1 output multiplexer is used. This multiplexer comprises buffer amplifiers A3 (142), A4 (144), and A5 (148) that receive the respective input, switch part S5 (150), and amplifier A7 (152) for amplifying the signals for output. Preferably multiplexer 140 is a high-speed multi-input/1 output video MUX having high insulation performance.

This part of the device is formed from a multiplexer. It should be noted that it is possible to keep the cost of the device low and the size of the device small when compared to when this part of the device is formed from three Photo MOS relays as shown by S1 (112).

The routes when each filter is used are as follows:
Output path P1 using LPF1
IN-A1-R1-S1 (CLOSE)-LPF1-A3-S5-A7-R6-OUT
Output path P2 using LPF2
IN-A1-R1-S2(CLOSE)-LPF2-A4-S5-A7-R6-OUT
Output path P3 using LPF3
IN-A1-A2-R5-LPF3-A5-S5-A7-R6-OUT|

LPF3 (124) in particular is a structure where there is no relay inserted on the input side. It should therefore be noted that regardless of the OPEN/CLOSE status of S1 (112) and S2 (114), signals that have been given to input terminal IN (102) are always applied to LPF3 (124). The output of buffer amplifier A1 having a low output impedance is connected to the input of buffer amplifier A2 having a high input impedance; therefore, it is possible to disregard changes in voltage that are applied to path P3 as a result of path 1 and path 2 switching operations.

Next, the operation of filter switching device 100 of the disclosed embodiments will be described using switching of the filter from LPF1 (118) to LPF2 (120) as an example.
C1) First, filter LPF1 (118) has been selected. This is the state wherein relay S1 (112) is closed and switch part S5 (150) of MUX (140) connects buffer amplifier A3 (142) and amplifier A7 (157). The signals comprising the AC component and the DC component applied to input terminal 102 are output to output terminal 156 via filter LPF1 (118).
C2) Next, the AC component of the signal to be applied to input terminal 102 is stopped. The DC component continues to be applied.
C3) S5 (150) of MUX (140) switches in such a way that buffer amp A5 (148) and amp A7 (152) are connected. The signals having a DC component only that have been applied to input terminal 102 pass through low-pass filter LPF3 (124) having the lowest cutoff frequency and are output from output terminal OUT (156). The signals applied to input terminal IN (102) are always applied to LPF3 (124) via buffer amplifiers A1 (104) and A2 (108); therefore, the effect of charging current to the capacitor inside filter LPF3 (124) can be disregarded.
C4) S1 (112) is opened and then S2 (114) is closed. Although charging current flows to capacitor LPF2 (120) as a result of closing S2 (114), MUX (140) is connected to LPF3 (124), not LPF2 (120); therefore, the input of LPF3 (124) is buffered and amplified by buffer amplifier A2 (108), and changes in current flowing through characteristic resistor R1 (106) have no effect. Therefore, the effect of the charging current is not manifested at output terminal 156.
C5) After waiting until the charging current to LPF2 (120) is stable, S5 (150) of MUX (140) switches in such a way that buffer amplifier A4 (144) and amplifier A7 (152) are connected. In this case, output of a level equivalent to the output level of the DC component output by LPF3 (124) is output through LPF2 (120).
C6) The system begins to supply an AC component of a new frequency matching LPF2 to signals to be given to input terminal IN.

As described above, when filter switching device 100 is used, primarily, signals of input terminal 102 are always given to filter LPF3 (124) having the lowest cutoff frequency via buffer amplifier A2 (108), and high-speed, multi-input/one output (or multi-pole/single-throw (MPST)) multiplexer 140 is used, and it is therefore possible to switch low-pass filters without discontinuous changing of the signal level of the DC component.

Moreover, the case wherein the AC component overlapping the DC component of the signal is switched from the AC component matching LPF1 (118) to the AC component matching LPF3 (124) by filter switching device 100 of FIG. 1, or when it is switched from the AC component matching LPF3 (124) to the AC component matching LPF1 (118) can be easily explained by the above-mentioned steps C1 through C6 and a description is therefore omitted here.

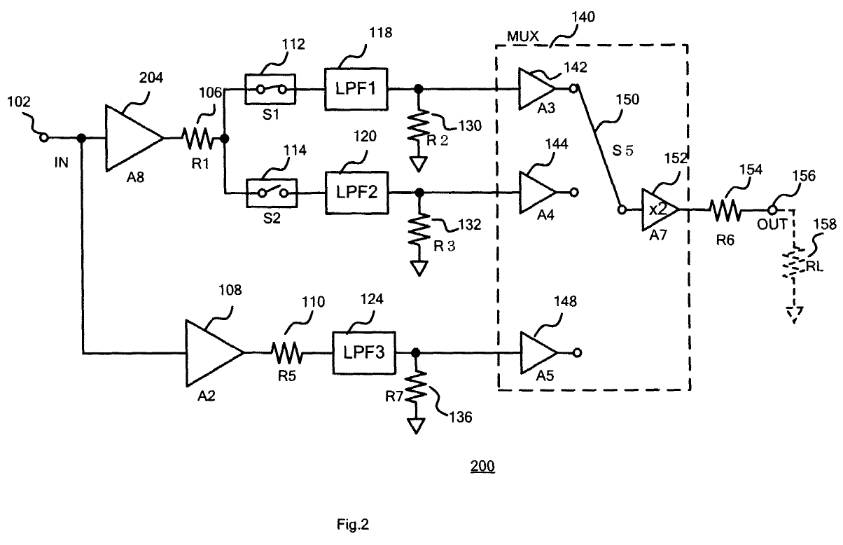

Next, a filter switching device 200 in FIG. 2 will be described as another preferred embodiment. Here, the same reference numerals are used for the same structural elements as in FIG. 1. For easy understanding, load resistor RL (158) is shown at output terminal OUT (156), but this is not a structural element of device 200.

FIG. 2 shows an embodiment wherein a buffer amplifier is added and isolation performance is enhanced on the path 1 side of the branching point between path P1 and path P3 so that the effect of changes in voltage when LPF1 (118) and LPF2 (120) are switched will not be transmitted to LPF3 (124) in the filter switching device shown in FIG. 1. That is, a buffer amplifier A8 (204) is disposed in front of characteristic resistor R1 (106) in FIG. 2 and buffer amplifier A8 (204) absorbs any changes in voltage downstream from characteristic resistor R1 (106); therefore, the effect of changes in voltage on buffer amplifier A2 (108) is alleviated. It should be noted that buffer amplifier A1 (104) of FIG. 1 is not always necessary in FIG. 2 and is therefore not shown.

The filter switching method of filter switching device 200 in FIG. 2 is the same as the description for FIG. 1 and therefore is not described here.

Various embodiments are described above, but various modifications based on the concepts disclosed herein are possible. For instance, although a filter switching device having three low-pass filters is described in FIGS. 1 and 2, it is possible to use four or more low-pass filters. In this case, the low-pass filter having the lowest cutoff frequency is connected to the circuit of buffer amplifier A2 (108) and the remaining low-pass filters are connected to characteristic resistor R1 (106) as a parallel circuit. Moreover, when there are two low-pass filters, it is possible to eliminate the low-pass filter LPF2 (120) circuit and relay S1 (112) in FIGS. 1 or 2.

What is claimed is:

1. A filter switching device, comprising:
a first buffer amplifier;
a first characteristic resistor connected at one terminal thereof to an output of the first buffer amplifier;
first and second filter circuits connected the other terminal of the first characteristic resistor, wherein
the first filter circuit comprises a first relay and a first low-pass filter, the first relay being connected between the first characteristic resistor and the first low-pass filter, and
the second filter circuit comprises a second relay and a second low-pass filter, the second relay being connected between the first characteristic resistor and the second low-pass filter;
a third filter circuit connected to the output of the first buffer amplifier, wherein
the third filter circuit comprises
a second buffer amplifier,
a second characteristic resistor, and
a third low-pass filter,
wherein the second buffer amplifier is connected to the output of the first buffer amplifier the second characteristic resistor is connected between the second buffer amplifier; and the third low-pass filter, and wherein the third low-pass filter has a lower cutoff frequency than cutoff frequencies of the first and the second low-pass filters
a third characteristic resistor; and
a multiplexer having inputs connected to the first, second, and third filter circuits and an output connected to the third characteristic resistor, the multiplexer being operable to connect one of the first, second, and third filter circuit to the third characteristic resistor.

2. The filter switching device according to claim 1, further comprising first, second, and third termination resistors connected to outputs of the first, second, and third low-pass filters, respectively.

3. The filter switching device according to claim 1, wherein the multiplexer comprises
third, fourth, and fifth buffer amplifiers; and
an output amplifier:
wherein the third, fourth and fifth buffer amplifiers are connected to the respective inputs of the multiplexer to buffers and amplify any signals thereat, and the output amplifier is connected to the third characteristic resistor to further amplify the signals from the third, fourth, or fifth buffer amplifier before the signals reach the third characteristic resistor.

4. The filter switching device according to claim 1, wherein during use to switch propagation of signals at an input of the first buffer amplifier through the first filter circuit to the third characteristic resistor, to propagation of the signals through the second filter circuit to the third characteristic resistor,
the multiplexer is switched from connecting the first filter circuit to the third characteristic resistor, to connecting the third filter circuit to the third characteristic resistor,
then the first relay is opened and the second relay is closed, and
then the multiplexer is switched from connecting the third filter circuit to the third characteristic resistor, to connecting the second filter circuit to the third characteristic resistor.

5. A filter switching device, comprising:
a first buffer amplifier;
a first characteristic resistor connected at one terminal thereof to an output of the first buffer amplifier;
first and second filter circuits connected to the other terminal of the first characteristic resistor, wherein
the first filter circuit comprises a first relay and a first low-pass filter, the first relay being connected between the first characteristic resistor and the first low-pass filter, and
the second filter circuit comprises a second relay and a second low-pass filter, the second relay being connected between the first characteristic resistor and the second low-pass filter;
a third filter circuit connected to the input of the first buffer amplifier, wherein the third filter circuit comprises
a second buffer amplifier,
a second characteristic resistor, and
a third low-pass filter.
wherein the second buffer amplifier is connected to the input of the first buffer amplifier, the second characteristic resistor is connected between the second buffer amplifier and the third low-pass filter, and wherein the third low-pass filter has a lower cutoff frequency than cutoff frequencies of the first and the second low-pass filters;
a third characteristic resistor; and
a multiplexer having inputs connected to the first, second, and third filter circuits and an output connected to the third characteristic resistor, the multiplexer being operable to connect one of the first, second, and third filter circuit to the third characteristic resistor.

6. The filter switching device according to claim 5, wherein during use to switch propagation of signals at an input of the first buffer amplifier through the first filter circuit to the third characteristic resistor, to propagation of the signals through the second filter circuit to the third characteristic resistor,
the multiplexer is switched from connecting the first filter circuit to the third characteristic resistor, to connecting the third filter circuit to the third characteristic resistor,
then the first relay is opened and the second relay is closed, and
then the multiplexer is switched from connecting the third filter circuit to the third characteristic resistor, to connecting the second filter circuit to the third characteristic resistor.

7. A filter switching method for
a filter switching device comprising
a first buffer amplifier, an output switching circuit connected to the first buffer amplifier, the output switching circuit comprising:
a first filter circuit and a second filter circuit, wherein
the first filter circuit comprises
a first relay connected between the first buffer amplifier and a first low-pass filter, and
the second filter circuit comprises
a second relays connected between the first buffer amplifier and a second low-pass filter
a third filter circuit comprising
a second buffer amplifier and send these signals connected between the first buffer amplifier and a third low-pass filter having a lower cutoff frequency than the cutoff frequencies of the first and the second low-pass filters,
the method comprising:
closing the first relay to complete a signal path through the first filter circuit;
connecting an output of the filter switching circuit to the first filter circuit to allow signals at the input of the first buffer amplifier to propagate through the first filter circuit to the output of the filter switching device;
allowing the signals to also propagate through the third filter circuit while the signals propagate through the first filter circuit;
disconnecting the output of the filter switching circuit from the first filter circuit and connecting the output of the filter switching circuit to the third filter circuit;
opening the first relay to break the signal path through the first filter circuit and closing the second relay to complete a signal path through the second filter circuit; and
disconnecting the output of the filter switching circuit from the third filter circuit and connecting the output of the filter switching circuit to the second filter circuit.

8. The filter switching method according to claim 7, wherein connecting and disconnecting the output of the filter switching circuit is carried out using a multiplexer.

9. The filter switching method according to claim 7, wherein the second buffer amplifier connected between the first buffer amplifier and the third low-pass filter comprises a second buffer amplifier whose input is connected to one of the input and the output of the first buffer amplifier.
